(19) United States
(12) Patent Application Publication
(10) Pub. No.: US 2014/0118961 A1
(43) Pub. Date: May 1, 2014

(54) POWER MODULE PACKAGE

(71) Applicant: SAMSUNG ELECTRO-MECHANICS CO., LTD., Suwon (KR)

(72) Inventors: Chang Seob Hong, Suwon (KR); Young Hoon Kwak, Suwon (KR); Kwang Soo Kim, Suwon (KR); Bum Seok Suh, Suwon (KR)

(73) Assignee: SAMSUNG ELECTRO-MECHANICS CO., LTD., Suwon (KR)

(21) Appl. No.: 13/757,576

(22) Filed: Feb. 1, 2013

(30) Foreign Application Priority Data
Oct. 29, 2012 (KR) 10-2012-0120555

(51) Int. Cl. H05K 7/20

(52) U.S. Cl. CPC H05K 7/2089
USPC 361/747; 361/728

(57) ABSTRACT

Disclosed herein is a power module package including: a base substrate; a post having one end and the other end, the one end being formed on the base substrate; and a case formed on the base substrate such that it covers a lateral surface and an upper surface of the base substrate, and spaced apart from the upper surface of the base substrate.

### CROSS REFERENCE TO RELATED APPLICATION

This application claims the benefit of Korean Patent Application No. 10-2012-0120555, filed on Oct. 29, 2012, entitled “Power Module Package”, which is hereby incorporated by reference in its entirety into this application.

### BACKGROUND OF THE INVENTION

1. Technical Field

The present invention relates to a power module package.

2. Description of the Related Art

Various types of power module packages including a power module package disclosed in Patent document 1 mentioned below tend to be integrated and reduced in size in line with an increase in energy consumption, increasing a heat generation rate, so, currently, it is a main concern to improve cooling efficiency.

Heat, rather than simply increased temperature, causes thermal deformation of a structure, greatly affecting a life span of components, and thus, research into a structure for enhancing cooling performance for solving the problems has been actively ongoing.

However, a complicated structure for enhancing efficiency results in an increase in unit cost in case of mass-production, and thus, a highly efficient modular structure which is simple and can be easily fabricated is required.

Also, a power module package is fabricated by bonding various materials having different coefficients of thermal expansion, potentially involving deformation such as warpage due to the difference in the coefficients of thermal expansion to reduce heat transfer rate, which leads to an increase in heat resistance to result in a degradation of cooling performance. Thus, a method for improving structural flatness is required.

When a power module package is designed to have a structure capable of improving cooling performance and reducing structural deformation, components thereof will maintain an even lift span to result in eventually maintaining a lengthened life span of a product overall.

### PRIOR ART DOCUMENT

(Patent Document 1) U.S. Pat. No. 7,208,819 B

### SUMMARY OF THE INVENTION

The present invention has been made in an effort to provide a power module package in which a thermally expandable post is formed on a base substrate to actively control warpage of the base substrate when a module is operated.

According to a preferred embodiment of the present invention, there is provided a power module package including: a base substrate; a post having one end and the other end, the one end being formed on the base substrate; and a case formed on the base substrate such that it covers a lateral surface and an upper surface of the base substrate, and spaced apart from the upper surface of the base substrate.

The post may be made of a metal.

The post may be made of copper.

The post may be combined onto the base substrate through a welding process or a soldering process.

The post may be formed such that other end thereof is in contact with an inner surface of the case.

The power module package may further include: a heat sink formed under the base substrate.

The power module package may further include: a boss formed on an inner surface of the case to fasten the post, wherein the other end of the post is inserted into the boss.

A size of the interior of the boss based on a length direction of the substrate may be the same as or smaller than a size of the post based on the length direction of the substrate.

The power module package may further include a semiconductor device mounted on the base substrate.

The power module package may further include a silicon gel member formed to fill the interior of the case.

A plurality of posts may be provided.

According to another preferred embodiment of the present invention, there is provided a power module package including: a base substrate; a post having one end and the other end and made of a thermally expandable material, the one end being combined onto the base substrate and the other end being in contact with the case; and a case formed on the base substrate to cover a lateral surface and an upper surface of the base substrate and spaced apart from the upper surface of the base substrate.

### BRIEF DESCRIPTION OF THE DRAWINGS

The above and other objects, features, and advantages of the present invention will be more clearly understood from the following detailed description taken in conjunction with the accompanying drawings, in which:

FIG. 1 is a cross-sectional view illustrating a configuration of a power module package according to an embodiment of the present invention.

FIG. 2 is a view illustrating a heat transmission process when the power module package of FIG. 1 operates.

FIG. 3 is a cross-sectional view illustrating a configuration of a power module package according to another embodiment of the present invention.

### DESCRIPTION OF THE PREFERRED EMBODIMENTS

The objects, features, and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side”, and the like, are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

Power Module Package

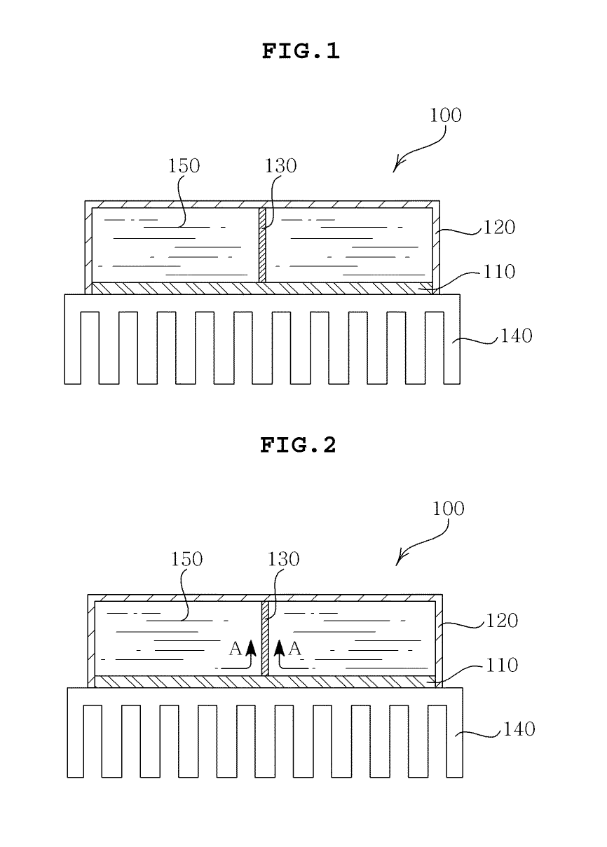

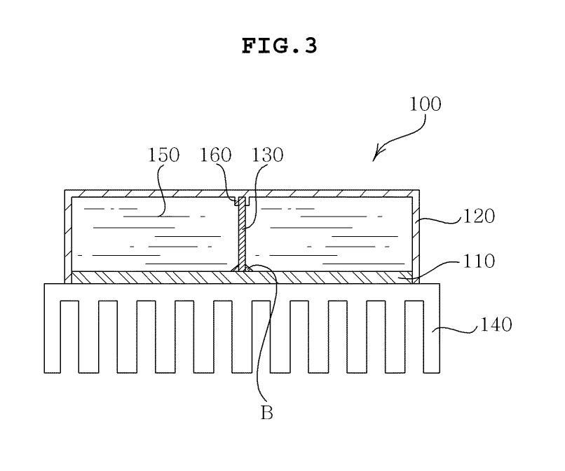

FIG. 1 is a cross-sectional view illustrating a configuration of a power module package according to an embodiment of the present invention. FIG. 2 is a view illustrating a heat transmission process when the power module package of FIG. 1 operates. FIG. 3 is a cross-sectional view illustrating a configuration of a power module package according to another embodiment of the present invention.

As illustrated in FIG. 1, a power module package 100 includes a base substrate 110, a post 130 having one end and the other end, the one end being formed on the base substrate 110, and a case 120 formed on the base substrate 110 such that it covers a lateral surface and an upper surface of the base substrate 110. In this case, the post 130 is formed to be spaced apart from the upper surface of the base substrate 110.

The base substrate 110 may be a general insulating layer applied as a core substrate in the field of a printed circuit board (PCB) or a printed circuit board having a circuit including one or more layers of connection pads formed on an insulating layer.

As the insulating layer, a resin insulating layer may be used.

As the resin insulating layer, a thermosetting resin such as an epoxy resin, a thermoplastic resin such as polyimide, a resin impregnated with a reinforcing material such as glass fiber or an inorganic filler, e.g., a pre-preg, may be used, or a thermosetting resin and/or a photo-curable resin, or the like, may also be used but the present invention is not particularly limited thereto.

Solder balls are formed as an external connection terminal on the connection pad through a follow-up process, and a semiconductor device or an external component is electrically connected to an inner layer circuit through the solder balls.

In case of the circuit including the connection pads, any metal used as a conductive metal for a circuit in the field of a circuit board may be applied without restriction, and typically, copper is used in a PCB.

The post 130 may be made of a metal, e.g., copper, but the present invention is not limited thereto and any material having excellent coefficient of thermal expansion and heat conductivity may be used.

Namely, the post 130 has one end and the other end and is formed such that one end thereof is combined onto the base substrate 110 and the other end thereof is in contact with the case 120, and here, the post 130 may be made of a thermally expandable material.

When combined onto the base substrate 110, the post 130 may be formed on a circuit layer formed on the base substrate 110 or on a non-circuit layer region.

Here, a region in which the post 130 is to be formed may be determined in consideration of prompt transmission (indicated by A in FIG. 2) of heat that may be generated from the base substrate 110 including a semiconductor device to be mounted on the base substrate 110, to the post 130,

A plurality of posts 130 may be provided.

For example, a plurality of posts 130 may be formed in regions of the base substrate 110 which are warped or expected to be warped.

As illustrated in FIG. 1, the post 130 may be formed such that other end thereof is in contact with an inner surface of the case 120.

Also, a size of the foregoing post 130 may be determined in consideration of buckling.

In detail, a slenderness ratio is a value obtained by dividing a characteristic length by a radius of gyration. Based on the slenderness ratio, pillars may be classified into a shorter pillar (0<slenderness ratio<60), an intermediate pillar (60<slenderness ratio<120), and a longer pillar (120<slenderness ratio<300). In the case of the shorter pillar, since the ratio of the pillar length to an effective area is small, no buckling is generated.

In this case, the radius of gyration is the square root of a value obtained by dividing a secondary section moment by a sectional area, and the characteristic length Lₑ refers to a length reflecting an aspect of deformation which is changed as both ends of a pillar are restricted along with a length of the pillar.

Namely, the post 130 according to an embodiment of the present invention may be designed in a slenderness ratio not causing buckling (e.g., equal to or less than 60 as the slenderness ratio).

As illustrated in FIG. 3, the post 130 may be combined onto the base substrate 110 (i.e., a region ‘B’ in FIG. 3) through a welding process such as ultrasonic welding, resistance welding, or the like, or a soldering process, but the combining method is not limited thereto.

In case of applying a separate combining member to combine the post 130 onto the base substrate 110, a combining member made of a material (e.g., a metal) that may be able to smoothly transmit heat may be applied, in consideration of heat transmission from the base substrate 110 to the post 130.

Also, as illustrated in FIG. 3, the power module package 100 may further include a boss 160 formed on an inner surface of the case 120 to fasten the post 130.

Here, the other end of the post 130 may be inserted into the boss 160.

Namely, the post 130 may be inserted such that it is interference-fitted into the boss 160.

To this end, a size of the interior of the boss 160 based on a length direction of the base substrate 110 (namely, a size of the region of the boss 160 in which the post 130 is inserted) may be the same as or smaller than a size of the post 130 based on the length direction of the substrate 110.

In this case, the sameness does not mean a thickness having precisely the same dimensions in a mathematical sense but may mean substantially sameness in consideration of design tolerance (or a structural error), a fabrication error, a measurement error, and the like.

When a plurality of posts 130 are formed, obviously, a plurality of bosses may be formed to correspond to the posts 130, respectively.

Meanwhile, the power module package 100 may further include a heat sink 140 formed under the base substrate 110.

The heat sink 140 may be made of a metal, but the present invention is not limited thereto and any material may be used to form the heat sink 140 as long as it can enhance heat dissipation characteristics.

Also, the power module package 100 may further include a semiconductor device (not shown) mounted on the base substrate 110.

Also, the power module package 100 may further include a silicon gel member 150 formed to fill the interior of the case 120.

Meanwhile, the case 120 disclosed in the present embodiment may be made of any material as long as it can maintain rigidity sufficiently resistant to deformation due to pressure resulting from thermal expansion of the post 130.

In general, a case type power module package uses a substrate fabricated by bonding elements made of materials having different coefficients of thermal expansion (CTE). In case of the substrate, since elements have different coefficients of thermal expansion, and thicknesses, patterns, and the like, of upper and lower portions of the substrate are different, thermal deformation occurs due to heat generated when the substrate is fabricated or when the power module package is operated.

The power module package according to an embodiment of the present invention can prevent the substrate from being deformed by the post made of thermally expandable material.

Also, after a fabrication process of a product is completed, when heat is generated from the semiconductor device and transmitted to the post through a lead frame, a circuit pattern, and the like, in the power module package, a length of the post is increased due to thermal expansion, and thus, the post positioned between the case and the base substrate presses both sides. In this case, since pressure applied to the base substrate is stronger due to the rigidity of the case, warpage of the base substrate can be improved.

In addition, since deformation of the base substrate of the power module package according to an embodiment of the present invention is controlled, when the base substrate comes into contact with the heat sink in assembling the heat sink, a contact surface therebetween is uniform, limiting a heat resistance deviation, and thus, heat dissipation characteristics can be enhanced.

According to the preferred embodiments of the present invention, since the thermally expandable post is formed on the base substrate in the power module package, the post can press the base substrate and the case when a module is operated, obtaining an effect of restraining the base substrate from being warped.

Also, since the post supporting the base substrate and the case is formed on the base substrate, a uniform surface of the base substrate can be maintained, and thus, when a heat sink is assembled, a contact surface with the heat sink is uniformly formed, improving heat transmission efficiency.

Although the embodiments of the present invention have been disclosed for illustrative purposes, it will be appreciated that the present invention is not limited thereto, and those skilled in the art will appreciate that various modifications, additions, and substitutions are possible, without departing from the scope and spirit of the invention.

Accordingly, any and all modifications, variations, or equivalent arrangements should be considered to be within the scope of the invention, and the detailed scope of the invention will be disclosed by the accompanying claims.

What is claimed is:

1. A power module package comprising:
a base substrate;
a post having one end and the other end, the one end being formed on the base substrate; and
a case formed on the base substrate such that it covers a lateral surface and an upper surface of the base substrate, and spaced apart from the upper surface of the base substrate.

2. The power module package as set forth in claim 1, wherein the post is made of a metal.

3. The power module package as set forth in claim 1, wherein the post is made of copper.

4. The power module package as set forth in claim 1, wherein the post is combined onto the base substrate through a welding process or a soldering process.

5. The power module package as set forth in claim 1, wherein the post is formed such that other end thereof is in contact with an inner surface of the case.

6. The power module package as set forth in claim 1, further comprising:
a heat sink formed under the base substrate.

7. The power module package as set forth in claim 1, further comprising:
a boss formed on an inner surface of the case to fasten the post,
wherein the other end of the post is inserted into the boss.

8. The power module package as set forth in claim 7, wherein a size of the interior of the boss based on a length direction of the substrate is the same as or smaller than a size of the post based on the length direction of the substrate.

9. The power module package as set forth in claim 1, further comprising:
a semiconductor device mounted on the base substrate.

10. The power module package as set forth in claim 1, further comprising:
a silicon gel member formed to fill the interior of the case.

11. The power module package as set forth in claim 1, wherein a plurality of posts are provided.

12. A power module package comprising:
a base substrate;
a post having one end and the other end and made of a thermally expandable material, the one end being combined onto the base substrate and the other end being in contact with the case; and
a case formed on the base substrate to cover a lateral surface and an upper surface of the base substrate and spaced apart from the upper surface of the base substrate.
